(19) United States
(12) Patent Application Publication
(10) Pub. No.: US 2008/0057636 A1
(43) Pub. Date: Mar. 6, 2008

(54) Strained semiconductor device and method of making same

(76) Inventors: Richard Lindsay, Fishkill, NY (US); Joo-Chan Kim, Fishkill, NY (US)

Correspondence Address: SLATER & MATSIL LLP, 17950 PRESTON ROAD, SUITE 1000, DALLAS, TX, 75252, US

(21) Appl. No.: 11/521,809

(22) Filed: Sep. 15, 2006

Related U.S. Application Data
(60) Provisional application No. 60/841,601, filed on Aug. 31, 2006.

(51) Int. Cl. H01L 21/8238

(52) U.S. Cl. 438/199

(57) ABSTRACT

A method of making a semiconductor device is disclosed. A first heavily doped region of a first conductivity type is implanted in a first portion of the semiconductor body and a first upper surface anneal is performed. After performing the first upper surface anneal, a second heavily doped region of a second conductivity type is implanted in a second portion of the semiconductor body. After implanting the second heavily doped region, a second upper surface anneal is performed.

This application claims the benefit of U.S. Provisional Application No. 60/841,601 (Attorney Docket No. 2006 P 50407P), filed on Aug. 31, 2006, entitled “Strained Semiconductor Device and Method of Making Same”, which application is hereby incorporated herein by reference.

### CROSS-REFERENCE TO RELATED APPLICATIONS

This application relates to the following co-pending and commonly assigned patent applications: Ser. No. ______ (Attorney Docket No. 2006 P 50407), filed Sep. 15, 2006; and Ser. No. ______ (Attorney Docket No. 2006 P 50537), filed Sep. 15, 2006, which applications are hereby incorporated herein by reference.

This invention was made under a joint research agreement between Infineon Technologies AG and Samsung Electronics Co., Ltd.

### TECHNICAL FIELD

This invention relates generally to semiconductor devices and methods, and more particularly to devices and methods for modulating stress in transistors in order to improve performance.

### BACKGROUND

Semiconductor devices are used in a large number of electronic devices, such as computers, cell phones and others. One of the goals of the semiconductor industry is to continue shrinking the size and increasing the speed of individual devices. Smaller devices can operate at higher speeds since the physical distance between components is smaller. In addition, higher conductivity materials, such as copper, are replacing lower conductivity materials, such as aluminum. One other challenge is to increase the mobility of semiconductor carriers such as electrons and holes.

One technique to improve transistor performance is to strain (i.e., distort) the semiconductor crystal lattice near the charge-carrier channel region. Transistors built on strained silicon, for example, have greater charge-carrier mobility than those fabricated using conventional substrates. One technique to strain silicon is to provide a layer of germanium or silicon germanium. A thin layer of silicon may be grown over the germanium-containing layer. Since the germanium crystal lattice is larger than silicon, the germanium-containing layer creates a lattice mismatch stress in adjacent layers. Strained channel transistors may then be formed in the strained silicon layer.

Another technique is to provide a stress layer over the transistor. Variants of stress layers can be used for mobility and performance boost of devices. For example, stress can be provided by a contact etch stop layer (CESL), single layers, dual layers, stress memory transfer layers, and STI liners. Most of these techniques use nitride layers to provide tensile and compressive stresses; however other materials can be used in other applications, e.g., HDP oxide layers.

Another method of inducing strain into the transistor utilizes a modified shallow trench isolation (STI) region. One method includes lining an STI recess with a stressor before filling the recess with a dielectric. The stressor can then impart a stress onto the adjacent semiconductor.

In the field of CMOS transistors, n-channel and p-channel transistors typically require the application stress liners of opposite stress polarity in order to effectively increase carrier mobility. N-channel transistors usually require a tensile stress liner, while p-channel transistors usually require a compressive stress liner to increase carrier mobility. Because of the different device stress requirements, fabrication steps must taken to ensure that stresses of the correct polarity are applied to the different types of transistors. In some processes, a blanket SMT (Stress Memory Technique) layer is deposited after both the n-channel and p-channel source-drain implant steps but before annealing. To ensure that only the n-channel transistor is subject to stress, the SMT layer will typically be etched away from the p-channel transistor prior to annealing. A disadvantage with this technique, however, is that an additional mask is needed to define the area to be etched away.

### SUMMARY OF THE INVENTION

In one embodiment a semiconductor device is fabricated on a semiconductor body. A first heavily doped region of a first conductivity type is implanted in a first portion of the semiconductor body and a first upper surface anneal is performed. After performing the first upper surface anneal, a second heavily doped region of a second conductivity type is implanted in a second portion of the semiconductor body. After implanting the second heavily doped region, a second upper surface anneal is performed.

The foregoing has outlined rather broadly features of the present invention. Additional features of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a, 1b, 2a and 2b illustrate diagrams to explain one theory behind concepts of the present invention;

FIG. 3 illustrates a transistor device fabricated using concepts of the present invention;

FIGS. 4a-4g provide cross-sectional views of a present embodiment process; and

FIG. 5 illustrates a transistor device fabricated as a FinFET.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of preferred embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

The invention will now be described with respect to preferred embodiments in a specific context, namely a method for improving carrier mobility in a CMOS device. Concepts of the invention can also be applied, however, to other electronic devices. As but one example, bipolar transistors (or BiCMOS) can utilize concepts of the present invention.

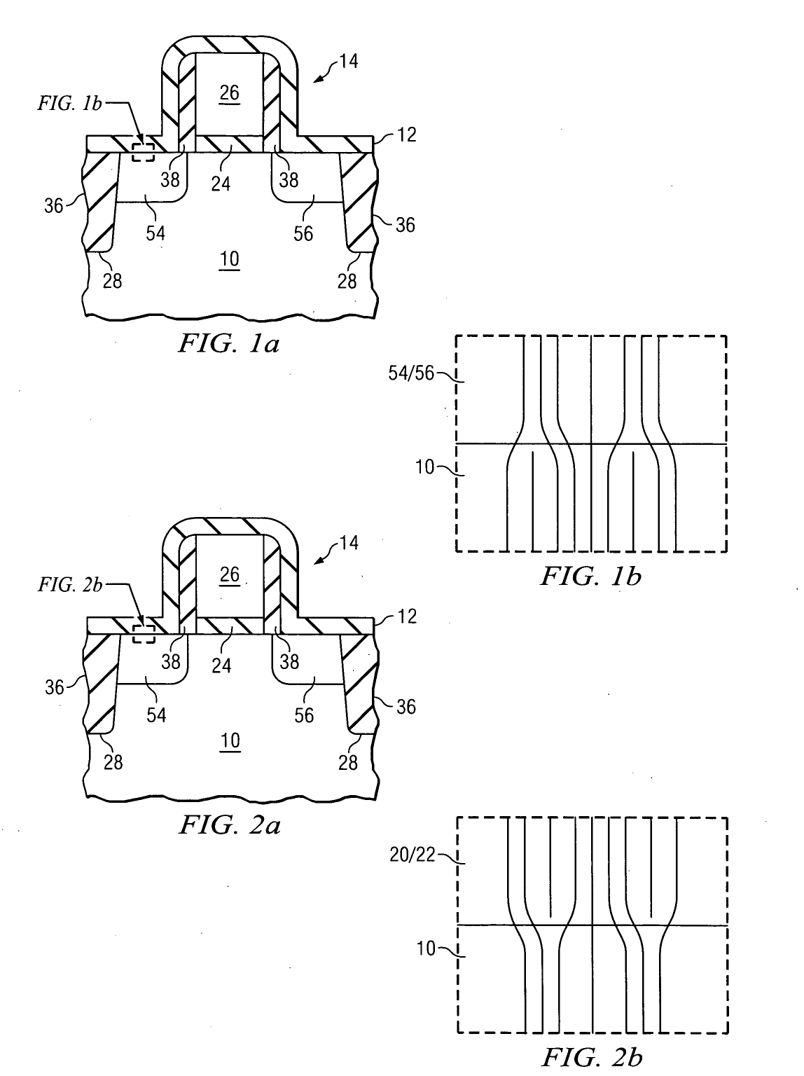

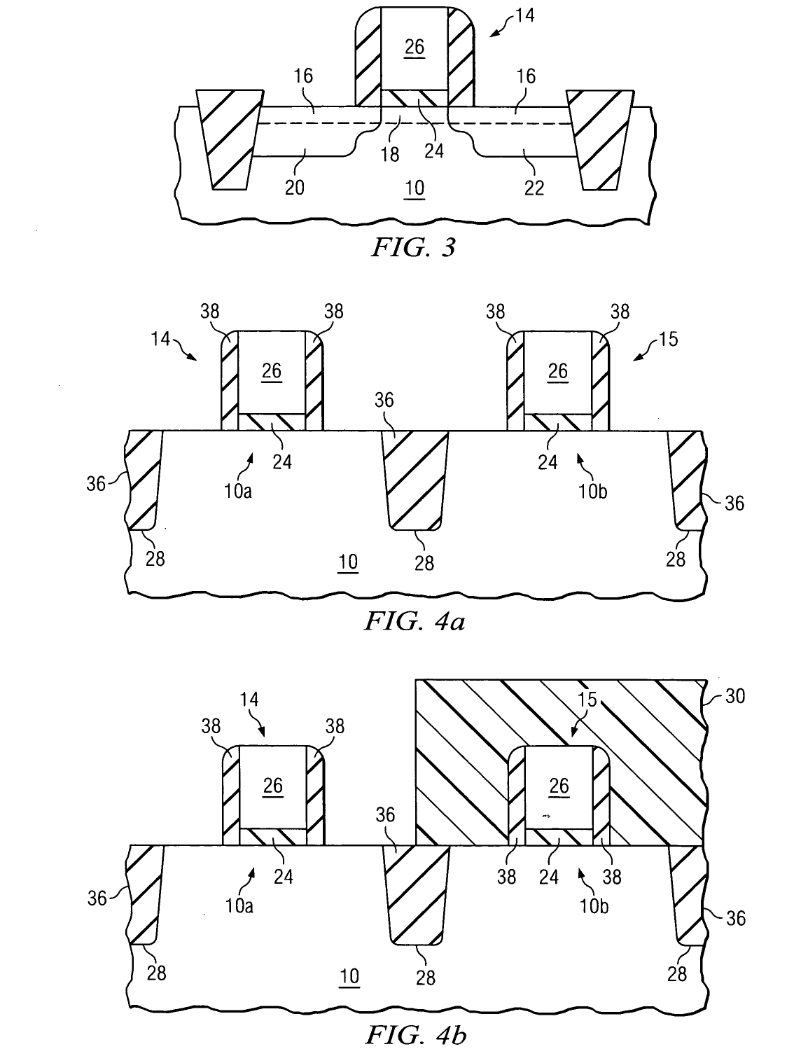

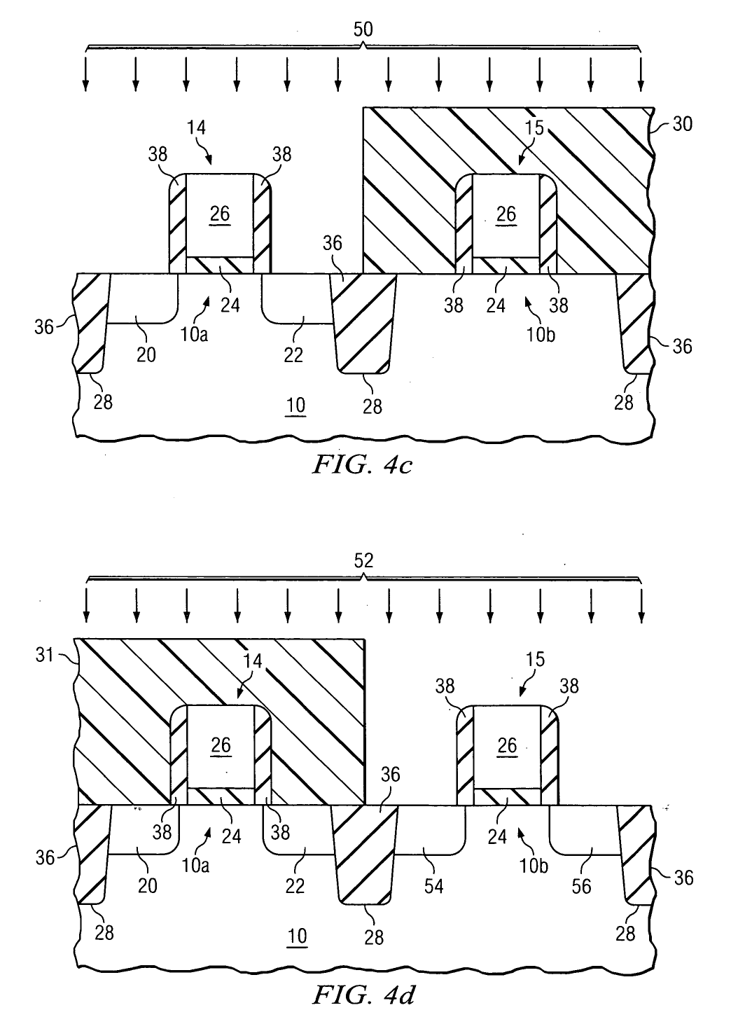

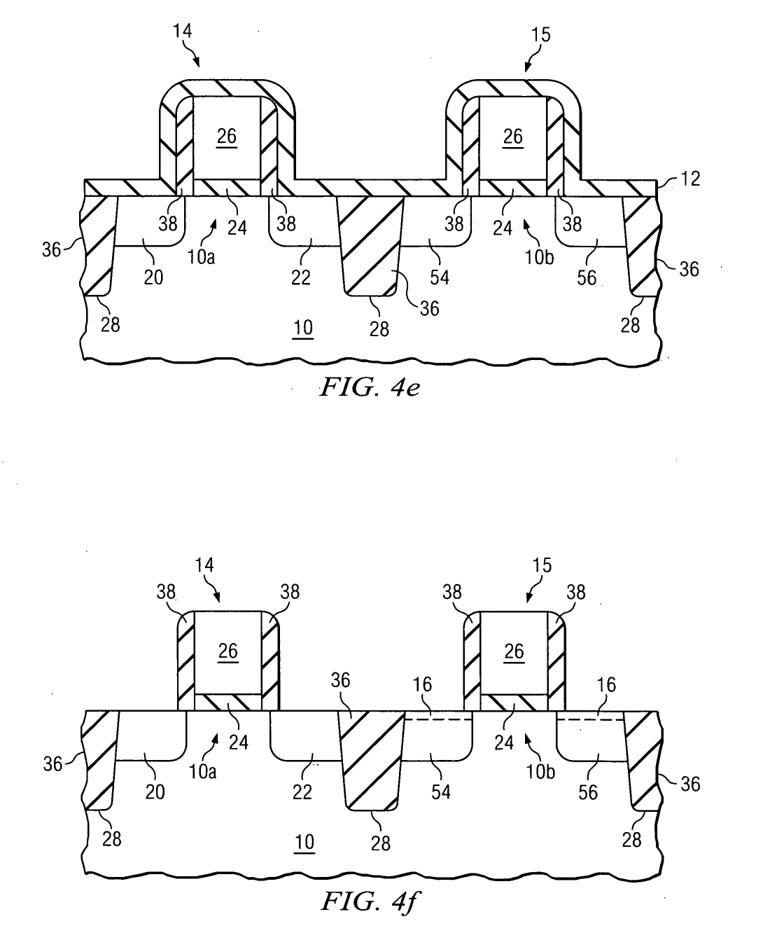

FIGS. 1 and 2 will first be used to describe one theory behind a basic concept of embodiments of the invention. An exemplary transistor device is shown in FIG. 3 and various methods for the formation of transistor devices using these concepts will then be described with respect to FIGS. 4a-4g.

The theory described herein is provided to aid in understanding. It must be understood, however, the invention is not bound by this theory. Experimental results show that stress remains in recrystallized silicon when topography exists. The explanations provided herein are the inventors' best understanding of why these phenomena occur.

In both FIG. 1, which includes FIGS. 1a and 1b, and FIG. 2, which includes FIGS. 2a and 2b, a semiconductor body 10 is shown. A gate dielectric 24 and gate electrode 26, along with spacer are formed over the body 10. A stress inducing layer 12 is formed over these elements. In the embodiment of FIG. 1, the layer 12 is a tensile liner, which can create a locally compressive stress in the semiconductor 10. This structure can be used preferentially for n-channel devices. In the embodiment of FIG. 2, the layer 12 is a compressive liner, which creates a tensile stress in the semiconductor 10. This structure can be used, for example, for p-channel devices.

In other embodiments, a compressive stress could benefit a p-channel device and/or a tensile stress could benefit an n-channel device. For example, it is possible that under certain geometries (e.g., edges) the strain could be opposite, i.e., a tensile liner may leave the substrate compressive in parts, e.g., at the edges. (It is also possible that the theory is inaccurate, leading to stresses different than those described herein.) In some embodiments, a biaxial stress will be created, thereby opening up possibilities for both pMOS and nMOS improvements with a tensile stress in the silicon.

FIGS. 1b and 2b show a representation of the boundary at the molecular level (and are clearly not to scale relative to FIGS. 1a and 2b).

The process illustrated in FIGS. 1 and 2 utilizes a stress memory technique at a point in the process flow after the source-drain ion implant. One goal is to include stress near the channel of these transistors by using the amorphizing properties of the source-drain ion implant and forming a stress liner over the entire partially fabricated transistor prior to annealing.

FIG. 1 shows the active area 10 for an n-channel transistor. In this case, a compressive stress can be generated from a tensile liner. Upon crystallization, the tensile liner 12 compresses the silicon at the amorphous/crystalline interface between source/drain area 54/56, and semiconductor body 10 such that some lattice planes stop growing. When the liner 12 is removed, a tensile stress is left in the active area. The fabrication of a transistor (see e.g., FIG. 3) can then be completed in the active area.

Similarly, FIG. 2 shows the active area 10 for a p-channel transistor. In this case, a tensile stress can be generated from a compressive liner. Upon crystallization, the compressive liner 12 stretches the silicon at the amorphous/crystalline interface between source/drain area 20/22, and semiconductor body 10 such that additional lattice planes may grow. Compressive SMT is not as effective for p-channel transistors as tensile SMT is for n-channel transistors because it is far more difficult to add lattice planes. When the liner 12 is removed, a compressive stress could be left in the active area. Once again, the transistor can be formed in the active area.

In FIG. 1b, the source/drain-substrate 54/56-10 interface is being compressed thus preventing some lattice planes from continuing into the (originally amorphized) source/drain 54/56 during recrystallization. In the case of FIG. 2b, the source/drain-substrate 20/22-10 interface is being stretched thereby allowing additional lattice planes to be created. In practice, the latter case is often more difficult to implement than the former so that the SMT technique works better for nFET and than pFET.

It should be noted that the stress memorization could also occur in a similar way by the recrystallization of the poly-Si gate in the stressed environment of the stressed liner. Indeed the most likely scenario is that there is a contribution from both the S/D and poly-Si recystallization. Again these are hypotheses and do not bound the scope of the invention. The effect of the SMT has been repeatedly proven in devices.

As a general point, in some cases, a local topography (e.g., near 90 degree edges) is needed to transfer stress from the liner to the silicon during regrowth. The theory is that if you have a flat film, each point in the film has a force pushing from left and right on the silicon, whereas at a 90° edge, there is only force in one direction (the other part is missing). (This is shown in the FIG. 1a). Vertical stresses are similarly found with vertical edges at the top of the gate, for example. Thus a flat, bare silicon wafer simply might not be significantly stressed—only at the wafer edges. From experiment, the stress is highest with maximum topography, with less stress remaining without edges.

FIG. 3 shows a transistor device 14 formed in the semiconductor body 10. In particular, the upper surface of the source and drain regions 20/22 is formed as a stress memory transfer region 16 (e.g., a strained semiconductor layer that was originally amorphized). The stress memory transfer region 16 extends throughout the source and drain 20 and 22 and can be formed as described above (and below). In many embodiments, the stress memory region 16 may be much deeper than illustrated in FIG. 3, typically half way between the bottom of the STI and the bottom of the doped region 20. Various specific examples are provided below. In the illustration of FIG. 3, a transistor device is formed.

The transistor 14 includes a channel region 18 disposed in the semiconductor body 10. This channel 18 is stressed from the adjacent source/drain regions 20 and 22. A gate dielectric 24 overlies the channel region 18 and a gate electrode 26 overlies the gate dielectric 24. A source region 20 and a drain region 22 are disposed in the semiconductor body and spaced from each other by the channel region 18. In one example, the stress memory region 16 is a tensile stress layer and the source region 20 and the drain region 22 are n+regions (and the transistor is therefore an n-channel transistor). In another example, the stress memory region 16 is a compressive stress layer and p+ source and drain regions 20 and 22 form a p-channel transistor.

In other embodiments, other semiconductor devices and elements can be fabricated in the stress memory transfer region 16. For example, if the doped regions 20 and 22 are formed of opposite polarities, the device 14 can be operated as a diode. In another example, the doped regions 20 and 22 can be used as contacts to one plate of a capacitor while the gate electrode 26 is used as another gate of a capacitor. This capacitor could be used, for example, as a decoupling capacitor between supply lines (e.g., V_{DD} and ground) on a semiconductor chip.

FIGS. 4a-4g will now be provided to illustrate various embodiments for forming a semiconductor device of the present invention. While certain details may be explained with respect to only one of the embodiments, it is understood that these details can also apply to other ones of the embodiments.

Referring first to FIG. 4a, a semiconductor body 10 is provided. A pair of partially fabricated transistors 14 is formed on the body 10. These transistors 14 include a gate dielectric 24, a gate electrode 26 and a spacer 38. In the preferred embodiment, the semiconductor body 10 is a silicon wafer. For example, the body 10 can be a bulk monocrystalline silicon substrate (or a layer grown thereon or otherwise formed therein) or a layer of a silicon-on-insulator (SOI) wafer. In other embodiments, other semiconductors such as silicon germanium, germanium, gallium arsenide or others can be used with the wafer.

In the first embodiment, isolation trenches 28 are formed in the semiconductor body 10. These trenches 28 can be formed using conventional techniques. For example, a hard mask layer (not shown), such as silicon nitride can be formed over the semiconductor body 10 and patterned to expose the isolation areas. The exposed portions of the semiconductor body 10 can then be etched to the appropriate depth. The trenches 28 define active areas 10a and 10b, in which integrated circuit components can be formed. In this embodiment, the trench regions 28 are filled with an insulating material to form trench isolation regions 36. For example, the trenches can be lined with a first material, e.g., SiN, and filled with a second material 36, e.g., an oxide deposited using a high density plasma process.

Gate dielectric 24 is deposited over exposed portions of the semiconductor body 10. In one embodiment, the gate dielectric 24 comprises an oxide (e.g., SiO₂), a nitride (e.g., Si₃N₄), or combination of oxide and nitride (e.g., SiON, oxide-nitride-oxide sequence). In other embodiments, a high-k dielectric material having a dielectric constant of about 5.0 or greater is used as the gate dielectric 24. Suitable high-k materials include HfO₂, HfSiO_{X}, Al₂O₃, ZrO₂, ZrSiO_{X}, Ta₂O₅, La₂O₃, nitrides thereof, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlON_{y}, ZrSiAlOₓ, ZrSiAlOₓN_{y}, combinations thereof, or combinations thereof with SiO₂, as examples. Alternatively, the gate dielectric 24 can comprise other high-k insulating materials or other dielectric materials. As implied above, the gate dielectric 24 may comprise a single layer of material, or alternatively, the gate dielectric 24 may comprise two or more layers.

The gate dielectric 24 may be deposited by chemical vapor deposition (CVD), atomic layer deposition (ALD), metal organic chemical vapor deposition (MOCVD), physical vapor deposition (PVD), or jet vapor deposition (JVD), as examples. In other embodiments, the gate dielectric 24 may be deposited using other suitable deposition techniques. The gate dielectric 24 preferably comprises a thickness of about 10 Å to about 60 Å in one embodiment, although alternatively, the gate dielectric 24 may comprise other dimensions.

In the illustrated embodiment, the same dielectric layer is used to form the gate dielectric 24 for both the p-channel and n-channel transistors. This feature is not required, however. In an alternate embodiment, the p-channel transistors and the n-channel transistor each have different gate dielectrics.

The gate electrode 26 is formed over the gate dielectric 24. The gate electrode 26 preferably comprises a semiconductor material, such as polysilicon or amorphous silicon, although alternatively, other semiconductor materials may be used for the gate electrode 26. In other embodiments, the gate electrode 26 may comprise TiN, HfN, TaN, W, Al, Ru, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, a partially silicided gate material, a fully silicided gate material (FUSI), other metals, and/or combinations thereof, as examples. In one embodiment, the gate electrode 26 comprises a doped polysilicon layer underlying a silicide layer (e.g., titanium silicide, nickel silicide, tantalum silicide, cobalt silicide, platinum silicide).

If the gate electrode 26 comprises FUSI, for example, polysilicon may be deposited over the gate dielectric 24, and a metal such as nickel can deposited over the polysilicon. Other metals may alternatively be used. The substrate 10 can then be heated to about 600 or 700° C. to form a single layer of nickel silicide. The gate electrode 26 can comprise a plurality of stacked gate materials, such as a metal underlayer with a polysilicon cap layer disposed over the metal underlayer. A gate electrode 26 between about 500 to 2000 Å thick may be deposited using CVD, PVD, ALD, or other deposition techniques.

The p-channel transistors and the n-channel transistor preferably include gate electrodes 26 formed from the same layers. If the gate electrodes include a semiconductor, the semiconductor can be doped differently for the p-channel transistors and the n-channel transistors. In other embodiments, the different types of transistors can include gates of different materials and/or thicknesses.

The gate layer (and optionally the gate dielectric layer) are patterned and etched using known photolithography techniques to create the gate electrodes 26 of the proper pattern. After formation of the gate electrodes, lightly doped source/drain regions (not shown) can be implanted using the gate electrode 26 as a mask. Other implants (e.g., pocket implants, halo implants or double diffused regions) can also be performed as desired.

Spacers 38, which are formed from an insulating material such as an oxide and/or a nitride, can be formed on the sidewalls of the gate electrode 26. The spacers 38 are typically formed by the deposition of a conformal layer followed by an anisotropic etch. The process can be repeated for multiple layers, as desired.

FIG. 4b illustrates the formation of a resist layer 30 over one of the active regions 10b. Accordingly, active region 10a is left exposed. The resist layer 30 can be any standard positive or negative tone photoresist, as an example.

In FIG. 4b, the resist is drawn to cover half of one of the filled trenches 36. It is noted that this type of processing can be difficult (but is certainly possible). For most purposes, it is sufficient to stop the resist anywhere in the trench 28 or over the active area 10a or 10b adjacent the trench.

Referring now to FIG. 4c, the upper surface of the exposed active area 10a is exposed to a p-type ion implant 50 forming the heavily doped source 20 and drain 22 regions. In the preferred embodiment, ions, which are depicted by the arrows 50, are implanted into the source-drain regions 20/22. For example, boron ions can be implanted with a dose of about 5×10¹⁴ cm⁻² to about 5×10¹⁵ cm⁻² and an implant energy between about 1 keV and about 5 keV. In other embodiments, other materials, such as BF₂, can be implanted.

The source drain ion implantation step also amorphizes the silicon and makes it sensitive to deformation using a stress inducing liner. In the preferred embodiment of the invention, the resist 30 is removed and a spike RTA step, typically at 900° C., is applied to the silicon to facilitate regrowth of crystals in the heavily doped source and drain regions of the p-channel transistor. The spike RTA step usually takes less than one second and is performed by increasing the temperature to its target, then immediately ramping down the temperature once it has reached the target. The annealing step can successfully occur, however, in temperatures ranging from about 550° C. to about 1000° C. The temperature of this intermediate RTA step is kept as low as possible to reduce dopant diffusion.

Referring to FIG. 4d, resist 31 is applied to the surface of the p channel transistor and the upper surface of 10b is exposed to an n-type ion implant 52, which forms the heavily doped source 54 and drain 50 regions of the n-channel transistor. In the preferred embodiment, arsenic or phosphorus ions, which are depicted by the arrows 52, are implanted into the source-drain regions 20/22. For example, As ions can be implanted with a dose of about 1×10¹⁵ cm⁻² to about 5×10¹⁵ cm⁻² and an implant energy between about 10 keV and about 50 keV. In other embodiments, other materials, such as P, can be implanted. Because of resist layer 30, the active area 10a and source-drain regions 20/22 will be unaffected, or at least substantially unaffected, by the ion implant process.

As shown in FIG. 4e, the resist layer 31 is removed and a liner 12 is deposited. The liner 12 is preferably a stress-inducing liner, as discussed above. For example, a nitride film (e.g., silicon nitride) is deposited in such a way as to create a stress between the film 12 and the underlying semiconductor 10. For a silicon nitride liner, typically the Si—N to Si—H bonding influences the stress direction—the lower Si—H to Si—N ratio, the more tensile. As is known in the art, deposition rate, pressure, UV curing, and other factors dictate this ratio. After the stress liner 12 is deposited, a second RTA is performed to recrystallize the n-type highly doped source drain regions 54 and 56. Since the p-type source/drain region 20 and 22 had previously been recrystallized, the stress liner will have only a minimal effect in these areas.

FIG. 4f depicts the structure after the amorphous layer is recrystallized to form stress memory region 16 as at least an upper portion of the source-drain regions 54/56. Since the active area 10a was recrystallized before the stress layer was applied, the crystalline structure of this region should not be substantially affected by the stress liner and subsequent RTA step. (e.g., the elasticity of the silicon crystal will allow the region to regain shape after liner removal). The subsequent RTA step, typically at 1050° C., is applied to the silicon to facilitate regrowth of crystals in the heavily doped source and drain regions of the n-channel transistor, as well as to activate the dopants. The RTA step is usually performed for between about 0-10 seconds. The annealing step can successfully occur, however, in temperatures greater than 1000° C.

In some embodiments, it has been found to be desirable to use a low temperature anneal for a compressive stressed semiconductor and a high temperature anneal for a tensile stressed semiconductor. (The theory is that H out-diffuses to give a lower Si—H/Si—N bond ratio as mentioned above.) For example, the low temperature recrystallization anneal can be performed at a temperature less than about 700° C., for example at between about 500° C. and about 600° C. The high temperature anneal can be performed at a temperature greater than about 1000° C., for example at between about 1100° C. and 1200° C. This intermediate RTA can also be used to neutralize stress in the other device, e.g. n-channel device instead of p-channel device.

Referring now to FIG. 4g, additional processing steps are illustrated. A contact etch stop layer 60, which is typically a nitride layer, is formed over the transistors 14. An interlayer dielectric (ILD) layer 622 is then formed over the etch stop layer. Suitable ILD layers include materials such as doped glass (BPSG, PSG, BSG), organo silicate glass (OSG), fluorinated silicate glass (FSG), spun-on-glass (SOG), silicon nitride, and PE plasma enhanced tetraethyloxysilane (TEOS), as examples. Typically, gate electrode and source/drain contacts (not shown) are formed through the interlayer dielectric. Metallization layers that interconnect the various components are also included in the chip, but not illustrated for the purpose of simplicity.

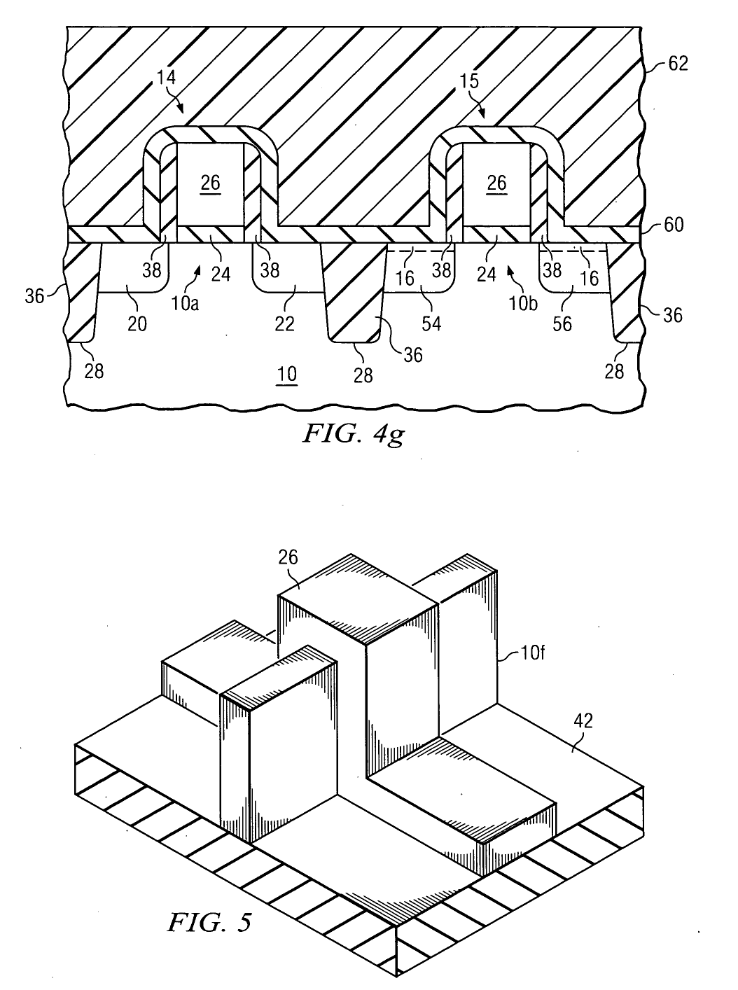

This concept of selectively stressing devices when applying a blanket stress liner can be used in alternative device architectures such as FinFETs or multi-gated devices. One example is shown in FIG. 5.

Referring first to FIG. 5, a fin 10f is formed over an insulating layer 42. The insulating layer 42 could be, for example, a buried oxide layer formed as part of an SOI substrate. The insulating layer 42 could overlie a substrate (not shown) made of silicon or another material. Alternatively, the fin 10f can be formed in a semiconductor without overlying an insulator 42.

To form the structure of FIG. 5, an SOI wafer is provided. The upper silicon layer is etched to form islands and fins, thereby electrically isolating each device. Gate 26 can be formed by depositing a conductor and etching the conductor to the appropriate pattern. The gate can be formed from any conductor, such as polysilicon, metal, metal nitride or conductive polymers. Exposed portions of the fin 10f can then be subjected to an ion implantation step and subsequently annealed and recrystallized after depositing the stress liner, so that the device retains stress, or the device can be annealed and recrystallized prior to depositing the stress liner so that the device does not retain stress.

Embodiments of the present invention can be utilized in conjunction with other stress-inducing techniques. For example, it is known to form the contact etch stop layer (CESL) 60 as a stress-inducing layer. Any stress induced by this layer can be additive to the stress already discussed above. As one example, co-pending application Ser. No. ______ (Attorney Docket No. 2006 P 50407) filed concurrently herewith, which is incorporated herein by reference, teaches an example of a stress-inducing layer 60. The techniques for forming this layer that are taught in that application can be applied here.

Another example of a stress-inducing technique is taught in co-pending application Ser. No. ______ (Attorney Docket No. 2006 P 50537) filed concurrently herewith, which is incorporated herein by reference. In this application, stress is induced directly into the gate 20 prior to formation of spacers 38. The process taught in this co-pending application can be utilized in conjunction with the techniques taught herein.

Yet another example of a stress inducing technique is taught in co-pending application Ser. No. 11/354,616, which was filed on Feb. 16, 2006 and is incorporated herein by reference. In this application, stress is induced in the active areas 10a and 10b prior to formation of the gate electrodes. Once again, the process taught in this co-pending application can be utilized with the techniques taught herein. In fact, any of the techniques from these applications can be combined as desired.

It will also be readily understood by those skilled in the art that materials and methods may be varied while remaining within the scope of the present invention. It is also appreciated that the present invention provides many applicable inventive concepts other than the specific contexts used to illustrate preferred embodiments. Accordingly, the appended claims are intended to include within their scope such processes, machines, manufacture, compositions of matter, means, methods, or steps.

What is claimed is:

1. A method of making a semiconductor device, the method comprising:
providing a semiconductor body;
forming a first gate over a first portion of the semiconductor body and a second gate over a second portion of the semiconductor body;
forming source/drain regions of a first conductivity type adjacent the first gate;
performing a first upper surface anneal;
forming source/drain regions of a second conductivity type adjacent the second gate, the second conductivity type being opposite the first conductivity type;
forming a liner over the semiconductor body; and
performing a second upper surface anneal.

2. The method of claim 1, further comprising removing the liner after performing the second upper surface anneal.

3. The method of claim 2, wherein the liner comprises a stress inducing liner.

4. The method of claim 1, wherein performing the first and second anneal comprises performing a rapid thermal anneal at a temperature of between 500° C. and 1000° C.

5. The method of claim 1, wherein forming a liner over the semiconductor body comprises forming the liner in direct contact with the semiconductor body.

6. The method of claim 1, wherein first conductivity type is the opposite of the second conductivity type.

7. The method of claim 6, further comprising:
forming a first transistor having a current path disposed within the upper layer of the first portion of the semiconductor body;
forming a second transistor having a current path disposed within the upper layer of the second portion of the semiconductor body.

8. The method of claim 7, wherein the first transistor is a p-channel transistor and the second transistor is an n-channel transistor.

9. The method of claim 7, wherein the first transistor is an n-channel transistor and the second transistor is a p-channel transistor.

10. A method of making a semiconductor device, the method comprising:
forming a first gate in a first active area and a second gate in a second active area;
implanting ions of a first conductivity type into the first active area thereby forming source/drain regions;
annealing the first active area to recrystallize any implantation damage caused by implanting ions of the first conductivity type;
implanting ions of a second conductivity type into the second active area thereby forming source/drain regions;
forming a stress inducing layer over the first and second active areas; and
annealing the second active area to recrystallize any implantation damage caused by implanting ions of the second conductivity type, whereby the stress inducing layer will cause a stress in the second active area.

11. The method of claim 10, wherein first conductivity type is the opposite of the second conductivity type.

12. The method of claim 11, wherein the stress inducing liner comprises a tensile stress inducing liner, wherein annealing the second active area comprises performing an anneal at a temperature less than about 700° C., and wherein forming a transistor comprises forming an n-channel field effect transistor.

13. The method of claim 11, wherein the stress inducing liner comprises a compressive stress inducing liner, wherein annealing the second active area comprises performing an anneal at a temperature greater than about 1000° C., and wherein forming a transistor comprises forming a p-channel field effect transistor.

14. A method of making a semiconductor device, the method comprising:
providing a semiconductor body;
implanting a first heavily doped region of a first conductivity type in a first portion of the semiconductor body;
performing a first upper surface anneal;
after performing the first upper surface anneal, implanting a second heavily doped region of a second conductivity type in a second portion of the semiconductor body, the second portion spaced from the first portion;
after implanting the second heavily doped region, forming a liner over the first and second portions of the semiconductor body; and
performing a second upper surface anneal.

15. The method of claim 14, wherein first conductivity type is the opposite of the second conductivity type.

16. The method of claim 14, further comprising forming a gate over the first and second portions of the semiconductor body prior to implanting the first heavily doped region of the first conductivity type.

17. The method of claim 14, further comprising forming a liner over the first and second portions of the semiconductor body prior to performing a second upper surface anneal.

18. The method of claim 17, wherein forming a liner comprises forming a tensile stress inducing liner.

19. The method of claim 17, wherein forming a liner comprises forming a compressive stress inducing liner.

20. A method of making a semiconductor device, the method comprising:
providing a first semiconductor fin overlying a first portion of a substrate and a second semiconductor fin overlying a second portion of the substrate;
forming a first gate electrode over a portion of the first semiconductor fin and a second gate electrode over a portion of the second semiconductor fin;
forming source/drain regions of a first conductivity type in the exposed regions of the first semiconductor fin;
performing a first anneal;
forming source/drain regions of a second conductivity type in the exposed regions of the second semiconductor fin;
forming a liner over the first semiconductor fin and the second semiconductor fin; and
performing a second anneal.

21. The method of claim 20, further comprising removing the liner after performing the second upper surface anneal.

22. The method of claim 21, wherein the liner comprises a stress inducing liner.

23. The method of claim 22, wherein the stress inducing liner comprises a tensile stress inducing liner, wherein annealing the second semiconductor fin comprises performing an anneal at a temperature less than about 1000° C., and wherein forming a transistor comprises forming an n-channel FinFET transistor.

24. The method of claim 22, wherein the stress inducing liner comprises a compressive stress inducing liner, wherein annealing the second semiconductor fin comprises performing an anneal at a temperature greater than about 900° C., and wherein forming a transistor comprises forming an p-channel FinFET transistor.

25. The method of claim 20, wherein performing the first and second anneal comprises performing a rapid thermal anneal at a temperature of between 500° C. and 1000° C.

26. The method of claim 20, wherein forming a liner over the semiconductor body comprises forming the liner in direct contact with the semiconductor body.

27. The method of claim 20, wherein the first conductivity type is the opposite of the second conductivity type.

28. The method of claim 27, further comprising:
forming a first transistor having a current path disposed within the first semiconductor fin; and
forming a second transistor having a current path disposed within the second semiconductor fin.

29. The method of claim 28, wherein the first transistor is a p-channel transistor and the second transistor is an n-channel transistor.
